(19) United States
(12) Patent Application Publication
(10) Pub. No.: US 2026/0047246 A1
(43) Pub. Date: Feb. 12, 2026

(54) SURFACE MOUNTABLE OPTOELECTRONIC DEVICE WITH SIDE WALLS INCLUDING SLOTS FILLED WITH A LAMINATED ENCAPSULANT MATERIAL

(71) Applicant: Dominant Opto Technologies Sdn Bhd., Melaka (MY)

(72) Inventors: LOW TEK BENG, Melaka (MY); LIM CHEE SHENG, Melaka (MY); TAN ENG WAH, Melaka (MY)

(21) Appl. No.: 19/362,170

(22) Filed: Oct. 17, 2025

Related U.S. Application Data
(63) Continuation-in-part of application No. 17/834,862, filed on Jun. 7, 2022, now Pat. No. 12,477,870.

(30) Foreign Application Priority Data
Apr. 7, 2022 (MY) PI 2022001857

(51) Int. Cl. H10H 20/854; H10H 20/80; H10H 20/85; H10H 20/851; H10H 20/855

(52) U.S. Cl. CPC H10H 20/854; H10H 20/8502; H10H 20/8506; H10H 20/8508; H10H 20/8512; H10H 20/855; H10H 20/882

(57) ABSTRACT

A surface mountable optoelectronic device with side walls including slots filled with a laminated encapsulant material is presented herein. A surface mount technology optoelectronic device includes a substrate, a housing, at least one optoelectronic chip, and an encapsulant material. The substrate includes electrical terminals that facilitate attachment and electrical coupling of the optoelectronic device to a physical circuit. The housing includes an opaque material and a cavity, in which the substrate is positioned at a bottom portion of the cavity, and a top portion of the housing includes a group of slot openings. The at least one optoelectronic chip is electrically connected to the electrical terminals, and is mounted, within the cavity, to the substrate. The encapsulant material is translucent or transparent, and has been included in the cavity and the slot openings.

### RELATED APPLICATION

The subject patent application is a continuation-in-part of, and claims priority to, U.S. patent application Ser. No. 17/834,862, filed Jun. 7, 2022, and entitled “SURFACE MOUNTABLE OPTOELECTRONIC DEVICE WITH SIDE WALLS INCLUDING SLOTS FILLED WITH A LAMINATED ENCAPSULANT MATERIAL”, which claims priority under 35 U.S.C. § 119 to Malaysia Pat. App. No. PI 2022001857, filed Apr. 7, 2022, and entitled “SURFACE MOUNTABLE OPTOELECTRONIC DEVICE WITH SIDE WALLS INCLUDING SLOTS FILLED WITH A LAMINATED ENCAPSULANT MATERIAL”, the entirety of which applications are hereby incorporated by reference herein.

### TECHNICAL FIELD

The subject disclosure generally relates to embodiments for a surface mountable optoelectronic device with side walls including slots filled with a laminated encapsulant material.

### BACKGROUND

Conventional LED technologies utilize LED packages that have housings. After an LED device is placed within a housing of an LED package, a viscous material is poured, injected, etc. into the housing and cured. Stress that has been applied to the LED package via, e.g., a change in temperature, a movement, a force, and/or a strain can cause cracks and other deformations of the LED package-negatively affecting optical properties, e.g., color and/or brightness, of the LED device. Further, such stress can cause delamination and/or separation of a cured material from the housing, and/or cause a loss of electrical contact of the LED device.

In this regard, conventional LED technologies have had some drawbacks, some of which may be noted with reference to the various embodiments described herein below.

### BRIEF DESCRIPTION OF THE DRAWINGS

Non-limiting embodiments of the subject disclosure are described with reference to the following figures, wherein like reference numerals refer to like parts throughout the various views unless otherwise specified:

FIG. 1 illustrates a block diagram of top and side views of an optoelectronic device, e.g., a surface mount technology (SMT) optoelectronic device, which comprises slots at corners of a housing of the optoelectronic device, in which the slots and a cavity within the housing are filled with a laminated encapsulant material, in accordance with various example embodiments;

FIG. 2 illustrates a block diagram of respective views of portions of a substrate of an optoelectronic device, a housing of the optoelectronic device comprising slots at corners of the housing, and a cavity within the housing and the slots being filled with a laminated encapsulant material, in accordance with various example embodiments;

FIG. 3 illustrates a block diagram of a top view of a housing of an optoelectronic device in which slots are included at corners of the housing and two sides of the housing, and an angled view of the optoelectronic device in which a cavity of the housing and the slots are filled with a laminated encapsulant material, in accordance with various example embodiments;

FIG. 4 illustrates a block diagram of a top view of a housing of an optoelectronic device in which slots are included at four sides of the housing, and an angled view of the optoelectronic device in which a cavity of the housing and the slots are filled with a laminated encapsulant material, in accordance with various example embodiments;

FIG. 5 illustrates a block diagram of side views of respective optoelectronic devices in which a top surface of an encapsulant material is not planar; the encapsulant material (e.g., a multilayer composite material) comprises two layers of respective materials; and a first layer of the encapsulant material (e.g., the multilayer composite material) is formed within a cavity of the housing, and a second layer of the encapsulant material is formed above the first layer, respectively, in accordance with various example embodiments;

FIG. 6 illustrates a block diagram of angled views of respective layers comprising a lead frame comprising a group of substrates, a housing frame comprising a group of housings, and an encapsulant sheet of an encapsulant material—the respective layers used to obtain, via a lamination process or a compression molding process, a composite structure comprising a group of optoelectronic devices, in accordance with various example embodiments; and

FIG. 7 illustrates a block diagram of an angled view of a composite structure comprising a group of optoelectronic devices that has been formed via a lamination process or a compression molding process, and a portion of the group of optoelectronic devices comprising an optoelectronic device, in accordance with various example embodiments.

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

As described above, conventional LED technologies have had some drawbacks with respect to stress (e.g., temperature, movement, force, and/or strain) that has been applied to an LED device—the stress causing cracks and/or deformation of the LED device; delamination and/or separation of a material that has been included in a housing of the LED device; and/or loss of electrical contact(s) within the LED device. Such stress negatively affects optical properties (e.g., color, brightness, light emission) of the LED device.

On the other hand, various embodiments disclosed herein can prevent and/or reduce cracks, deformation, delamination, separation, and/or loss of electrical contact(s), e.g., associated with stress that has been applied to an LED device, by including slots in a top portion of a housing of the LED device and filling the slots and a cavity of the housing with a laminated encapsulant material.

For example, an optoelectronic device comprises: a substrate comprising electrical contacts; a housing comprising an opaque material and a cavity, wherein a top portion of the housing comprises slot openings that extend from the cavity to an exterior of the housing; at least one optoelectronic chip that is electrically coupled to respective electrical contacts of the electrical contacts, and mounted to the substrate within the cavity; and an encapsulant material that has been included in the cavity and the slot openings and that comprises a wavelength conversion material and/or light scattering particles, wherein the wavelength conversion material converts a first wavelength of light from an optoelectronic chip of the at least one optoelectronic chip to a second wavelength of the light that is different from the first wavelength, and wherein the light scattering particles are configured to improve a color uniformity of the light.

In embodiment(s), a shape of a top surface of the encapsulant material comprises a convex lens, a Fresnel pattern, a microprism, or an aspheric surface, and wherein the shape is configured to alter a beam angle of the light.

In other embodiment(s), the optoelectronic chip comprises a blue light emitting chip or an ultraviolet light emitting chip, and wherein the encapsulant material comprises phosphor particles that convert the light from the blue light emitting chip or the ultraviolet light emitting chip into a white light.

In yet other embodiment(s), the light scattering particles comprise diffuser particles that facilitate an improvement in the color uniformity of the light and/or an improvement in an optical mixing of the light.

In embodiment(s), the slot openings are configured, e.g., during a lamination process or a compression molding process, to expel excess encapsulant material and/or vent trapped gas to facilitate a reduction of a void within the encapsulant material and/or a reduction in an incomplete filling of the encapsulant material within the cavity.

In other embodiment(s), at least a portion of the slot openings are diagonal and located at corners of the housing.

In yet other embodiment(s), the encapsulant material is within a defined tolerance of a preferred distance from the top portion of the housing.

In embodiment(s), the slot openings correspond to a defined slot depth from the top portion of the housing, and wherein the slot openings correspond to a defined slot width.

In other embodiment(s), the defined slot depth is within a defined tolerance of a preferred slot depth that is one half of a depth of the housing.

In yet other embodiment(s), the defined slot depth is within a defined tolerance of a preferred slot depth that is one fifth of a depth of the housing.

In embodiment(s), the defined slot width is within a defined tolerance of a preferred slot width that is one-tenth of a millimeter.

In other embodiment(s), the defined slot width is within a defined tolerance of a preferred slot width that is five-tenths of a millimeter.

In yet other embodiment(s), the optoelectronic chip comprises a photoemitter or a photodetector.

In embodiment(s), the slot openings facilitate a reduction of an effect, on the optoelectronic device, of an external stress that has been applied to the optoelectronic device by releasing the external stress via the slot openings and/or by improving an adhesion of the encapsulant material to the housing.

In other embodiment(s), the external stress comprises a temperature that has been applied to the optoelectronic device, a movement that has been applied to the optoelectronic device, a force that has been applied to the optoelectronic device, and/or a strain that has been applied to the optoelectronic device.

In yet other embodiment(s), the housing has been formed, via an applied defined pressure and an applied defined heat, from a plastic material.

In embodiment(s), an optoelectronic device comprises: a substrate comprising electrical contacts; a housing comprising an opaque material and a cavity, wherein a top portion of the housing comprises slot openings that extend from the cavity to an exterior of the housing; at least one optoelectronic chip that is electrically coupled to respective electrical contacts of the electrical contacts, and mounted to the substrate within the cavity; and a multilayer encapsulant structure comprising a first layer of material and a second layer of material, wherein the first layer of material is adjacent to the optoelectronic chip, wherein the second layer of material covers the first layer of material, wherein the multilayer encapsulant structure comprises a wavelength conversion material and/or light scattering particles, wherein the wavelength conversion material converts a first wavelength of light from an optoelectronic chip of the at least one optoelectronic chip to a second wavelength of the light that is different from the first wavelength, and wherein the light scattering particles facilitate an improvement in a color uniformity of the light and/or an improvement in an optical mixing of the light.

In other embodiment(s), a shape of the second layer comprises a convex lens, a Fresnel pattern, a microprism, or an aspheric surface; and the shape alters a beam angle of the light.

In yet other embodiment(s), the optoelectronic chip comprises a blue light emitting chip or an ultraviolet light emitting chip, and wherein the multilayer encapsulant structure comprises phosphor particles that convert the light from the blue light emitting chip or the ultraviolet light emitting chip into a white light.

In other embodiment(s), the light scattering particles comprise diffuser particles that facilitate the improvement in the color uniformity of the light and/or the improvement in an optical mixing of the light.

Various embodiments disclosed herein can improve LED-based device performance, e.g., with respect to LED color, LED brightness, and/or LED light emission, by including slots in a top portion of a housing of a corresponding LED package, and filling the slots and a cavity of the housing with a laminated encapsulant material to improve adhesion of such material to the housing, and in turn to prevent and/or reduce cracks, deformation, delamination, separation, and/or loss of electrical contact(s) of the LED package, e.g., associated with stress that has been applied to the LED package.

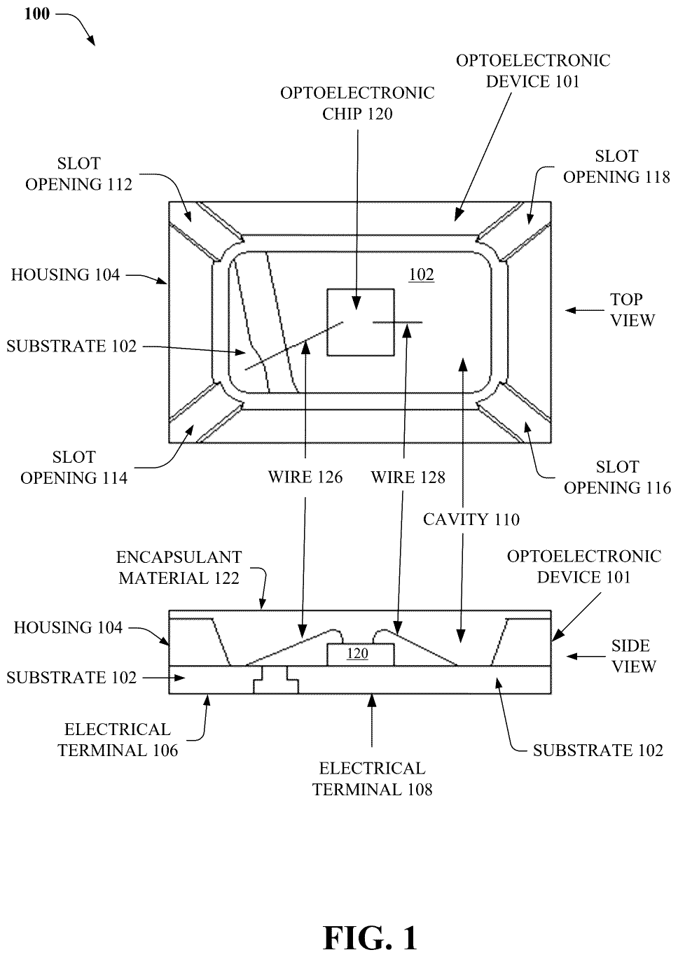

FIG. 1 illustrates a block diagram (100) of top and side views of an optoelectronic device (101), e.g., an SMT optoelectronic device, in accordance with various example embodiments. A substrate (102) comprises respective portions comprising electrical terminals (106, 108) that facilitate attachment and electrical coupling of the optoelectronic device to a physical circuit (not shown), e.g., a printed circuit board. In embodiment(s), the substrate comprises a metal, e.g., copper, a metal alloy, or other conductive material(s).

The housing comprises an opaque material and a cavity (110). In embodiment(s), the opaque material comprises a reflective plastic. In other embodiment(s), the housing has been formed, via an applied defined pressure and an applied defined heat, from a material, e.g., a plastic and/or a pellet-based material.

The substrate is positioned at a bottom portion of the cavity, and a top portion of the housing comprises slots corresponding to a group of slot openings (112, 114, 116, 118) that are diagonal and located at corners of the housing. In embodiment(s), the slot openings have a width (e.g., a defined slot width, a preferred slot width) of approximately 0.1 mm to 0.5 mm, e.g., within a defined tolerance of 0.01 mm. In other embodiment(s), the slots have a depth (e.g., a defined slot depth, a preferred slot depth) from the top portion of the housing between ½ of a height of the cavity/a depth of the housing to ⅕ the height of the cavity/the depth of the housing, e.g., within a defined tolerance (e.g., 0.01 mm).

In embodiment(s), the slot openings facilitate a reduction of an effect, on the optoelectronic device, of an external stress that has been applied to the optoelectronic device by releasing the external stress via the slot openings and/or by improving an adhesion of the encapsulant material to the housing.

In other embodiment(s), the external stress comprises a temperature that has been applied to the optoelectronic device, a movement that has been applied to the optoelectronic device, a force that has been applied to the optoelectronic device, and/or a strain that has been applied to the optoelectronic device.

An optoelectronic chip (120) (e.g., photoemitter, photodetector) is electrically connected, via wires (126, 128), to the electrical terminals, and is mounted, within the cavity, to the substrate. In embodiment(s) (not shown), more than one optoelectronic chip can be mounted within the cavity and connected to the electrical terminals.

In embodiment(s) (not shown), the optoelectronic chip is a flip-chip-based device, and is electrically coupled to the electrical terminals via solder bumps using, e.g., a controlled collapse chip connection of a flip-chip-based process.

An encapsulant material (122), e.g., a laminated encapsulant material, that is translucent or transparent is included and/or formed in the cavity and the slot openings—the encapsulant material being translucent or transparent so that optical radiation can be transmitted or received via the encapsulant material. In embodiment(s), the encapsulant material is aligned with the top portion of the housing. In other embodiment(s), the encapsulant material is formed 0.01 mm to 0.1 mm above the top portion of the housing, e.g., within a defined error tolerance of 0.001 mm.

In embodiment(s), the encapsulant material comprises a wavelength conversion material and/or light scattering particles. The wavelength conversion material converts a first wavelength of light from optoelectronic chip(s) (e.g., 120) of the optoelectronic device to a second wavelength that is different from the first wavelength; and the light scattering particles are configured to facilitate an improvement in a color uniformity of the light and/or an improvement in an optical mixing of the light.

In other embodiment(s), the optoelectronic chip comprises a blue light emitting chip or an ultraviolet light emitting chip; and the encapsulant material comprises phosphor particles that convert the light from the blue light emitting chip or the ultraviolet light emitting chip into a white light.

In yet other embodiment(s), the phosphor particles are uniformly dispersed or spatially distributed within the encapsulant material.

In embodiment(s), the light scattering particles comprise diffuser particles that facilitate the improvement in the color uniformity of the light and/or the improvement in the optical mixing of the light.

In other embodiment(s), the encapsulant material is formed, via a lamination (e.g., a sheet lamination) process or via a compression molding process, in the cavity and the slot openings, e.g., to expel excess encapsulant material and/or vent trapped gas to facilitate a reduction of void(s) within the encapsulant material and/or a reduction in incomplete filling(s) of the encapsulant material within the cavity. In this regard, in various embodiment(s), the encapsulant material comprises a sheet of pliable material that has been hardened, via a curing process corresponding to at least one of an applied heat or an applied pressure, during the lamination process.

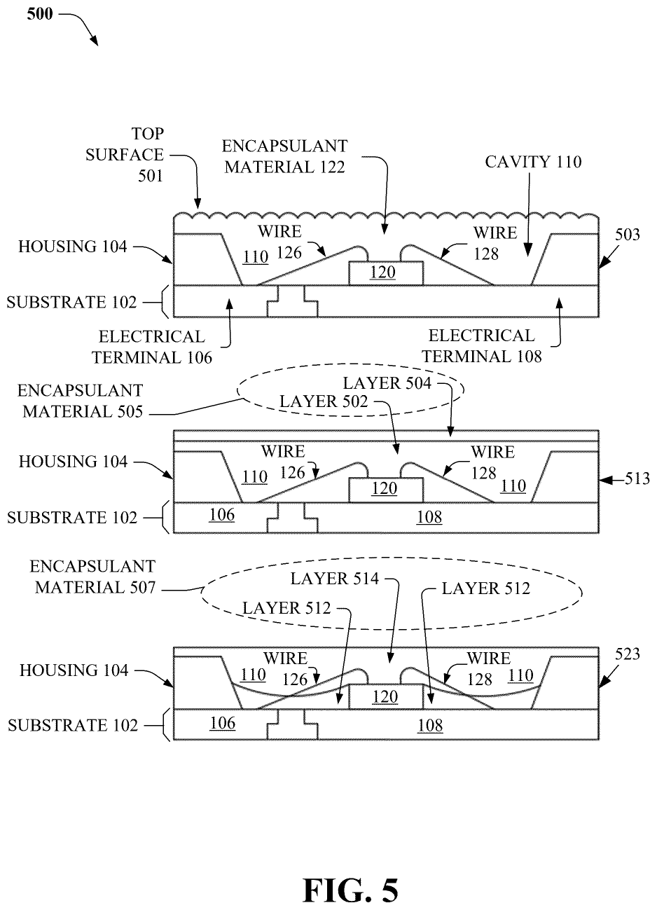

In yet other embodiments (see, e.g., FIG. 5 and related discussion below) the encapsulant material is a multilayer encapsulant structure comprising a first layer of material and a second layer of material. The first layer of material is adjacent to the optoelectronic chip; and the second layer of material covers the first layer of material.

In other embodiment(s), the multilayer encapsulant structure comprises a wavelength conversion material and/or light scattering particles, in which the wavelength conversion material (e.g., located within the first layer of material and/or located within the second layer of material) converts a first wavelength of light from an optoelectronic chip of the optoelectronic device to a second wavelength that is different from the first wavelength, and in which the light scattering particles comprise diffuser particles (e.g., located within the first layer of material and/or located within the second layer of material) that facilitate an improvement in a color uniformity of the light and/or an improvement in an optical mixing of the light.

In embodiment(s), the optoelectronic chip comprises a blue light emitting chip or an ultraviolet light emitting chip; and the multilayer encapsulant structure comprises phosphor particles (e.g., located within the first layer of material and/or located within the second layer of material) that convert the light from the blue light emitting chip or the ultraviolet light emitting chip into a white light.

In other embodiment(s), a shape of the second layer comprises a convex lens, a Fresnel pattern, a microprism, or an aspheric surface, and the shape alters a beam angle of the light.

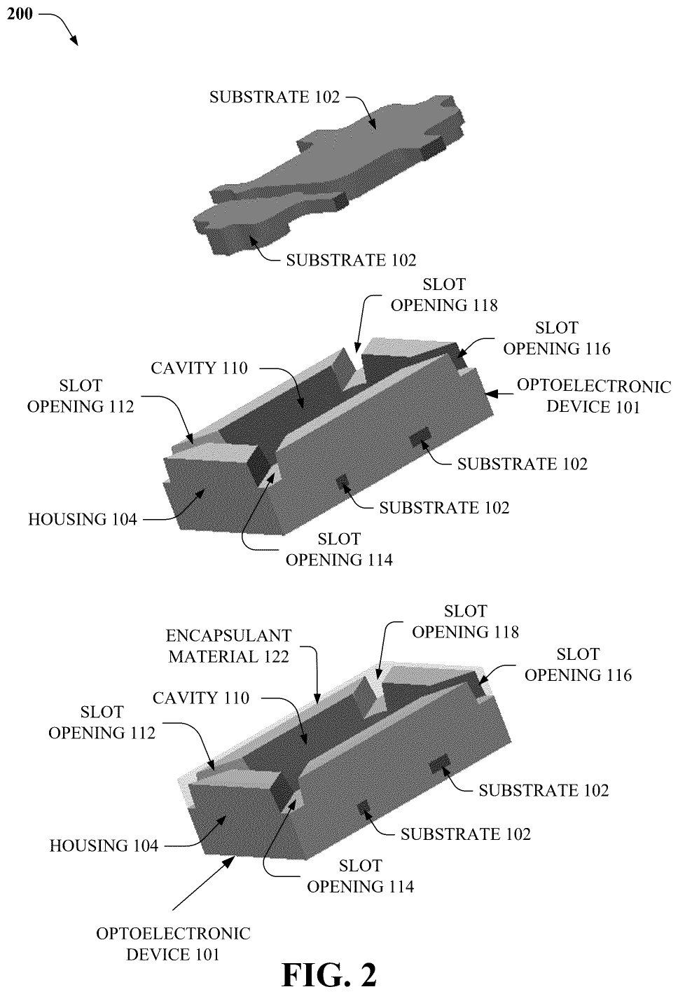

FIG. 2 illustrates a block diagram (200) of a first view of portions of a substrate of the optoelectronic device (101), a second view of a housing (104) of the optoelectronic device comprising slots corresponding to a group of slot openings (112, 114, 116, and 118) being diagonal and located at corners of the housing, and a third view of the slots and a cavity (110) of the housing being filled with an encapsulant material (122), e.g., a laminated encapsulant material.

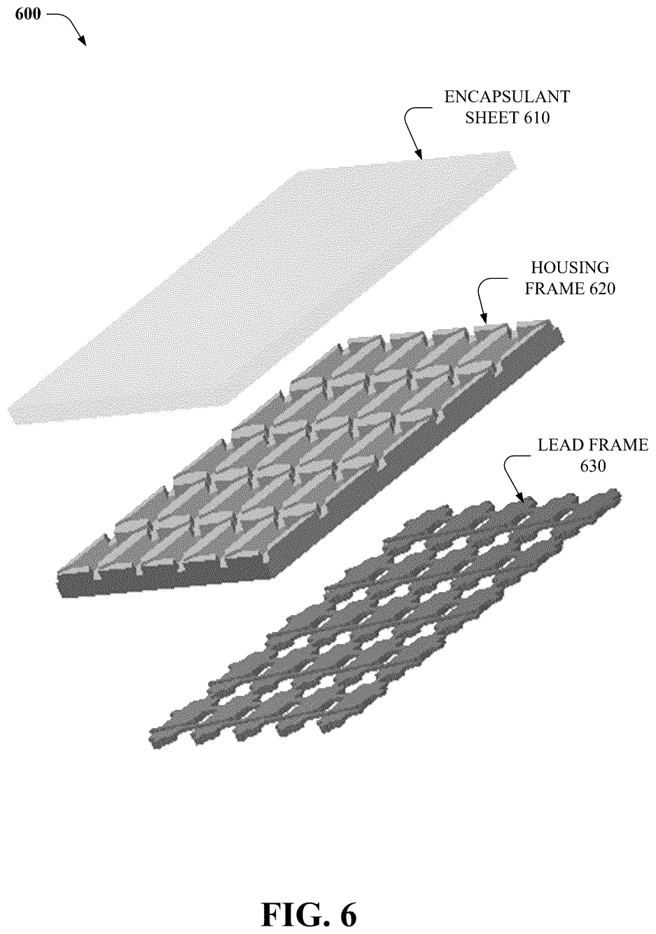

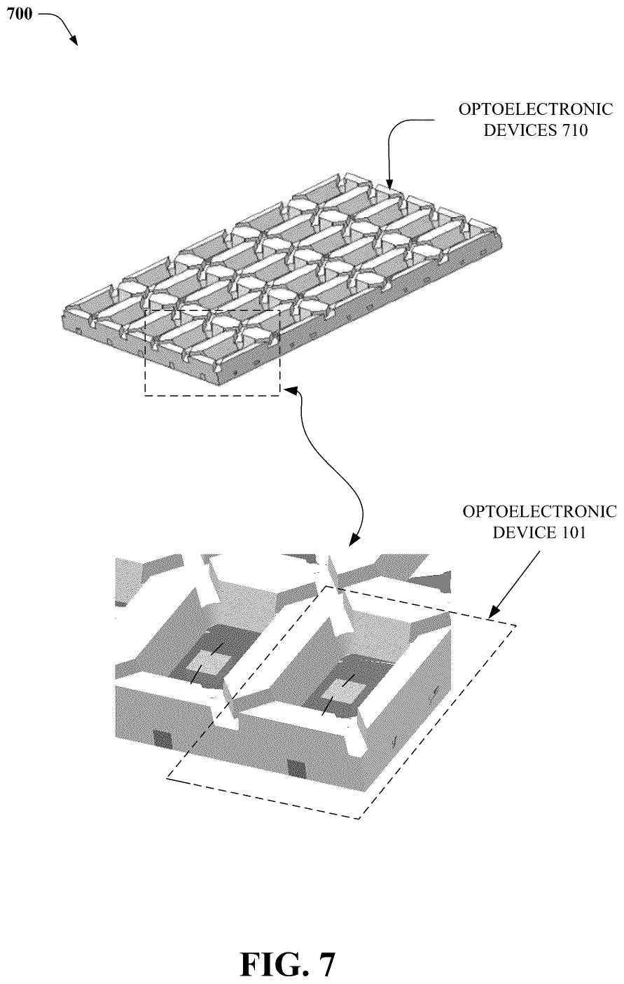

In this regard, in various embodiment(s) disclosed herein, the encapsulant material is laminated via a lamination process in which multiple layers, e.g., comprising the substrate, the housing, and the encapsulant material, are formed on and/or attached to respective layers of the multiple layers to obtain a composite structure comprising a group of optoelectronic devices comprising the optoelectronic device. (See, e.g., FIGS. 6-7 and related discussion below).

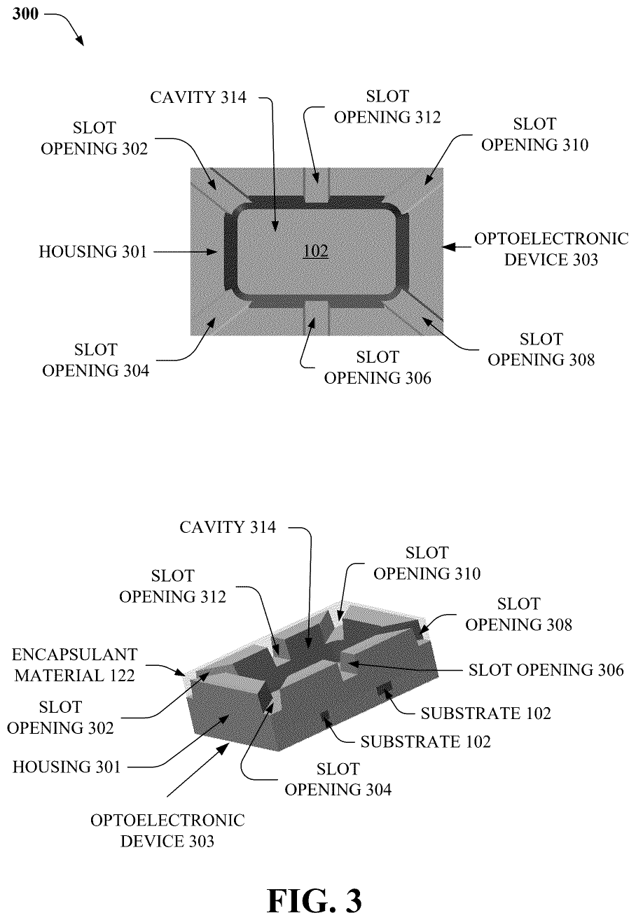

FIG. 3 illustrates a block diagram (300) of a top view of a housing (301) of an optoelectronic device (303) and an angled view of the optoelectronic device. As illustrated by the top and angled views, the housing of the optoelectronic device includes slots corresponding to a group of slot openings (302, 304, 306, 308, 310, 312), in which a first portion of the slot openings (302, 304, 308, 310) are diagonal and located at corners of the housing, and a second portion of the slot openings (306, 312) are located at opposite sides of the housing, e.g., perpendicular to respective sides of the housing. Further, as illustrated by the angled view of the optoelectronic device, the slots and a cavity (314) of the housing are filled with an encapsulant material (122), e.g., a laminated encapsulant material.

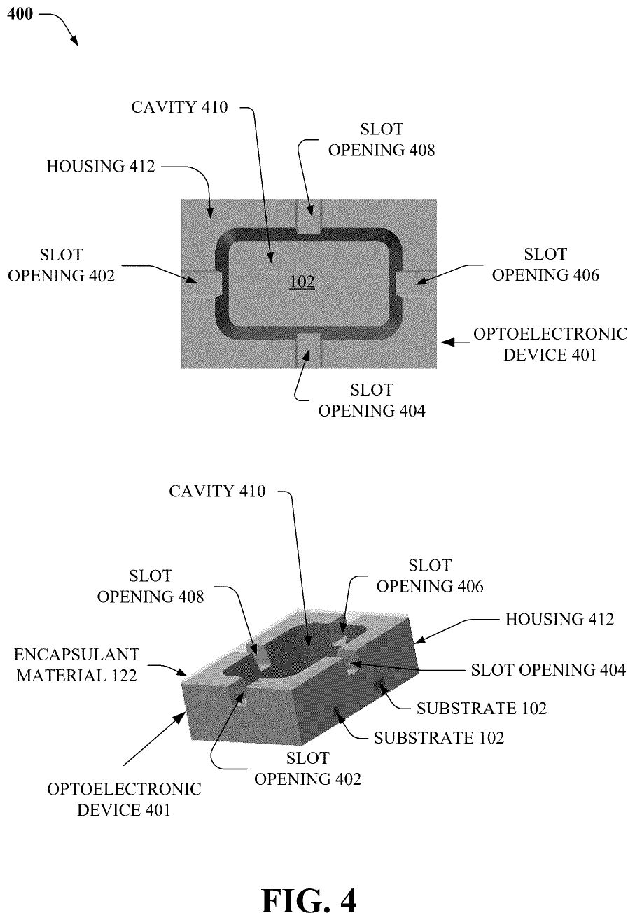

FIG. 4 illustrates a block diagram (400) of a top view of a housing (412) of an optoelectronic device (401) and an angled view of the optoelectronic device. As illustrated by the top and angled views, the housing of the optoelectronic device includes slots corresponding to a group of slot openings (402, 404, 406, 408) that are located at opposite sides of the housing, e.g., perpendicular to respective sides of the housing. Further, as illustrated by the angled view of the optoelectronic device, the slots and a cavity (410) of the housing are filled with an encapsulant material (122), e.g., a laminated encapsulant material.

FIG. 5 illustrates a block diagram of side views of respective optoelectronic devices (503, 513, 523), in accordance with various example embodiment(s). As illustrated by FIG. 5, a top surface (501) of an encapsulant material (122) of optoelectronic device 503 is not planar. In embodiment(s), a shape of the top surface comprises a convex lens, a Fresnel pattern, a microprism, or an aspheric surface, and is configured to alter a beam angle of light emitted from optoelectronic chip 120.

Encapsulant material (505) (e.g., a multilayer composite material/structure) of optoelectronic device 513 comprises two layers of respective materials (e.g., a first layer of material 502 and a second layer of material 504). The first layer of material (502) is adjacent to optoelectronic chip 120; and the second layer of material (504) covers the first layer of material.

In embodiment(s), the multilayer encapsulant material/structure comprises a wavelength conversion material and/or light scattering particles, in which the wavelength conversion material (e.g., located within the first layer of material and/or located within the second layer of material) converts a first wavelength of light from optoelectronic chip 120 of optoelectronic device 513 to a second wavelength that is different from the first wavelength, and in which the light scattering particles comprise diffuser particles (e.g., located within the first layer of material and/or located within the second layer of material) that facilitate an improvement in a color uniformity of the light and/or an improvement in an optical mixing of the light.

In other embodiment(s), the first layer of material comprises phosphor and is positioned adjacent to the optoelectronic chip for wavelength conversion, and the second layer of material is phosphor-free and comprises the diffuser particles to enhance color homogeneity of the light.

In yet other embodiment(s), the second layer of material is a mechanical protection layer to improve reliability of the optoelectronic device.

In other embodiment(s), optoelectronic chip 120 comprises a blue light emitting chip or an ultraviolet light emitting chip; and the multilayer encapsulant material/structure comprises phosphor particles (e.g., located within the first layer of material and/or located within the second layer of material) that convert the light from the blue light emitting chip or the ultraviolet light emitting chip into a white light.

Encapsulant material (507) (e.g., a multilayer composite material/structure) of optoelectronic device 523 comprises two layers of respective materials (e.g., a first layer of material 512 and a second layer of material 514). The first layer of material (512) is formed within cavity 110 and is adjacent to optoelectronic chip 120; and the second layer of material (514) is formed above the first layer of material.

Referring now to FIGS. 6 and 7, block diagram (600) illustrates angled views of respective layers comprising a lead frame (630) that comprises a group of substrates; a housing frame (620) comprising a group of housings that are adjacent to respective housings of the group of housings comprising respective cavities, in which top portions of the respective housings comprise respective groups of slot openings; and an encapsulant sheet (610) of an encapsulant material (e.g., 122, 505, 507). The respective layers are utilized, via a lamination process or a compression molding process, to form a composite structure comprising a group of optoelectronic devices (e.g., optoelectronic devices 710), in accordance with various example embodiments.

In embodiment(s), the encapsulant material is a pliable material or a translucent material, and the lamination process comprises forming and/or attaching the encapsulant sheet to the housing frame (e.g., comprising an opaque material), and filling the respective cavities and the slot openings with the encapsulant material.

For example, the encapsulant sheet is softened, e.g., via heat, into a viscous material that fills the respective groups of slot openings and the respective cavities, and then hardened, formed, and/or cured during the lamination process, e.g., via a curing process corresponding to a defined heat and/or a defined pressure that has been applied to the optoelectronic devices (710).

In embodiment(s), the housing is formed, via an applied defined pressure and an applied defined heat, from a pellet based and/or a plastic material.

In other embodiment(s), after the encapsulant material has been cured, a post-cure planarization process or a polishing process can be performed on the top surface of the encapsulant material, e.g., to reduce variation(s) in encapsulant height, to remove excess material within the group of slot openings, and/or to expose portion(s) of the slot openings to achieve a desired optical or mechanical property.

In yet other embodiment(s), the post-cure planarization process or the polishing process can utilize mechanical, chemical-mechanical, and/or plasma-based techniques to obtain a defined roughness of the top surface of the encapsulant material or a defined thickness of the encapsulant material.

In embodiment(s), the post-cure planarization process or the polishing process can utilize the mechanical, chemical-mechanical, and/or plasma-based techniques to enhance a color uniformity or a correlated color temperature (CCT) consistency of light that has been emitted via phosphor that has been included in the encapsulant material, e.g., by adjusting an effective optical path length of the light.

In other embodiment(s), a planarized encapsulant surface that has been generated via the post-cure planarization process facilitates subsequent packaging operations, such as lens attachment (to the planarized encapsulant surface) or thin-package assembly of the optoelectronic device.

In yet other embodiment(s), the encapsulant sheet is aligned with the top portions of the respective housings. In yet other embodiment(s), the encapsulant sheet is formed 0.01 mm to 0.1 mm above the top portions of the respective housings, e.g., within a defined error tolerance of 0.001 mm. In other embodiment(s), the encapsulant sheet is within a defined tolerance of a preferred distance from the top portion of the respective portions.

In embodiment(s), the optoelectronic devices (710), e.g., as a composite structure, are diced or sawed into discrete optoelectronic devices, e.g., optoelectronic device 101.

In other embodiment(s), respective portions of the respective substrates of the group of substrates are separated, via sawing, into respective pairs of substrates—the sawing creating respective gaps between the respective pairs of substrates, and each pair of substrates of the respective pairs of substrates corresponds to an optoelectronic device of the optoelectronic devices.

Reference throughout this specification to “one embodiment,” or “an embodiment,” means that a particular feature, structure, or characteristic described in connection with the embodiment is included in at least one embodiment. Thus, the appearances of the phrase “in one embodiment,” or “in an embodiment,” in various places throughout this specification are not necessarily all referring to the same embodiment. Furthermore, the particular features, structures, or characteristics may be combined in any suitable manner in one or more embodiments.

Further, to the extent that the terms “includes,” “has,” “contains,” and other similar words are used in either the detailed description or the appended claims, such terms are intended to be inclusive—in a manner similar to the term “comprising” as an open transition word-without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art having the benefit of the instant disclosure.

The above description of illustrated embodiments of the subject disclosure is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. An optoelectronic device, comprising:
a substrate comprising electrical contacts;
a housing comprising an opaque material and a cavity, wherein a top portion of the housing comprises slot openings that extend from the cavity to an exterior of the housing;
at least one optoelectronic chip that is
electrically coupled to respective electrical contacts of the electrical contacts, and
mounted to the substrate within the cavity; and
an encapsulant material that has been included in the cavity and the slot openings and that comprises at least one of a wavelength conversion material or light scattering particles, wherein the wavelength conversion material converts a first wavelength of light from an optoelectronic chip of the at least one optoelectronic chip to a second wavelength of the light that is different from the first wavelength, and wherein the light scattering particles are configured to improve a color uniformity of the light.

2. The optoelectronic device of claim 1, wherein a shape of a top surface of the encapsulant material comprises a convex lens, a Fresnel pattern, a microprism, or an aspheric surface, and wherein the shape is configured to alter a beam angle of the light.

3. The optoelectronic device of claim 1, wherein the optoelectronic chip comprises a blue light emitting chip or an ultraviolet light emitting chip, and wherein the encapsulant material comprises phosphor particles that convert the light from the blue light emitting chip or the ultraviolet light emitting chip into a white light.

4. The optoelectronic device of claim 1, wherein the light scattering particles comprise diffuser particles that facilitate at least one of an improvement in the color uniformity of the light or an improvement in an optical mixing of the light.

5. The optoelectronic device of claim 1, wherein the slot openings are configured, during a lamination process or a compression molding process, to at least one of expel excess encapsulant material or vent trapped gas to facilitate a reduction of at least one of a void within the encapsulant material or a reduction in an incomplete filling of the encapsulant material within the cavity.

6. The optoelectronic device of claim 1, wherein at least a portion of the slot openings are diagonal and located at corners of the housing.

7. The optoelectronic device of claim 1, wherein the encapsulant material is within a defined tolerance of a preferred distance from the top portion of the housing.

8. The optoelectronic device of claim 1, wherein the slot openings correspond to a defined slot depth from the top portion of the housing, and wherein the slot openings correspond to a defined slot width.

9. The optoelectronic device of claim 8, wherein the defined slot depth is within a defined tolerance of a preferred slot depth that is one half of a depth of the housing.

10. The optoelectronic device of claim 8, wherein the defined slot depth is within a defined tolerance of a preferred slot depth that is one fifth of a depth of the housing.

11. The optoelectronic device of claim 8, wherein the defined slot width is within a defined tolerance of a preferred slot width that is one-tenth of a millimeter.

12. The optoelectronic device of claim 8, wherein the defined slot width is within a defined tolerance of a preferred slot width that is five-tenths of a millimeter.

13. The optoelectronic device of claim 1, wherein the optoelectronic chip comprises a photoemitter or a photodetector.

14. The optoelectronic device of claim 1, wherein the slot openings facilitate a reduction of an effect, on the optoelectronic device, of an external stress that has been applied to the optoelectronic device by at least one of releasing the external stress via the slot openings or improving an adhesion of the encapsulant material to the housing.

15. The optoelectronic device of claim 14, wherein the external stress comprises at least one of a temperature that has been applied to the optoelectronic device, a movement that has been applied to the optoelectronic device, a force that has been applied to the optoelectronic device, or a strain that has been applied to the optoelectronic device.

16. The optoelectronic device of claim 1, wherein the housing has been formed, via an applied defined pressure and an applied defined heat, from a plastic material.

17. An optoelectronic device, comprising:
a substrate comprising electrical contacts;
a housing comprising an opaque material and a cavity, wherein a top portion of the housing comprises slot openings that extend from the cavity to an exterior of the housing;
at least one optoelectronic chip that is
electrically coupled to respective electrical contacts of the electrical contacts, and
mounted to the substrate within the cavity; and
a multilayer encapsulant structure comprising a first layer of material and a second layer of material, wherein the first layer of material is adjacent to the optoelectronic chip, wherein the second layer of material covers the first layer of material, wherein the multilayer encapsulant structure comprises at least one of a wavelength conversion material (e.g., a phosphor) or light scattering particles, wherein the wavelength conversion material converts a first wavelength of light from an optoelectronic chip of the at least one optoelectronic chip to a second wavelength of the light that is different from the first wavelength, and wherein the light scattering particles are configured to improve a color uniformity of the light.

18. The optoelectronic device of claim 17, wherein a shape of the second layer comprises a convex lens, a Fresnel pattern, a microprism, or an aspheric surface, and wherein the shape alters a beam angle of the light.

19. The optoelectronic device of claim 17, wherein the optoelectronic chip comprises a blue light emitting chip or an ultraviolet light emitting chip, and wherein the multilayer encapsulant structure comprises phosphor particles that convert the light from the blue light emitting chip or the ultraviolet light emitting chip into a white light.

20. The optoelectronic device of claim 17, wherein the light scattering particles comprise diffuser particles that facilitate at least one of an improvement in the color uniformity of the light or an improvement in an optical mixing of the light.
